(19) United States
(12) Patent Application Publication
(10) Pub. No.: US 2026/0323811 A1
(43) Pub. Date: Oct. 15, 2026

(54) SMALL LAYERED INTER-PHASE MANIFOLD

(71) Applicant: Raytheon Company, Arlington, VA (US)

(72) Inventors: Edward Lawrence Hieb, Aubrey, TX (US); Travis Mayberry, Dallas, TX (US); Jesus Gerardo Vera, McKinney, TX (US)

(21) Appl. No.: 19/642,057

(22) Filed: Apr. 8, 2026

Related U.S. Application Data
(60) Provisional application No. 63/787,351, filed on Apr. 11, 2025.

(51) Int. Cl. H05K 1/02; H05K 1/14; H05K 1/181; H05K 7/20

(52) U.S. Cl. CPC H05K 1/0203; H05K 1/144; H05K 1/181; H05K 7/20309; H05K 7/20318; H05K 7/20336; H05K 2201/064

(57) ABSTRACT

A cold plate structure includes a channel structure integrally formed with the cold plate structure and including a coolant. The cold plate structure includes a plurality of oscillating heat pipes integrally formed with the cold plate structure and configured to transfer heat from a target structure to the channel structure. The plurality of oscillating heat pipes are fluidically isolated from the channel structure. A method of manufacturing the cold plate structure includes integrally forming a channel structure with a body of the cold plate structure using additive manufacturing.

### CROSS-REFERENCE TO RELATED APPLICATIONS

This application claims the benefit of priority to U.S. Application No. 63/787,351 filed Apr. 11, 2025, the disclosure of which is incorporated herein by reference in its entirety.

### BACKGROUND

The present disclosure relates to a cold plate structure for cooling electronic components. The present disclosure relates to a small layered inter-phase manifold (SLIM) formed of oscillating heat pipes and bulk cooling channels. Particularly, for example, the present disclosure relates to a cold plate structure including embedded oscillating heat pipes and bulk cooling channels, in which the oscillating heat pipes and bulk cooling channels are fluidically isolated from one another. The present disclosure also relates to techniques for manufacturing the cold plate structure, and accordingly, for manufacturing an assembly including the cold plate structure.

Electronics packaging is trending towards higher heat-producing devices in smaller volumes. Techniques which support effective heat dissipation and prevent overheating in electronic components, particularly for instances of dense electronics packaging, are desired.

### BRIEF DESCRIPTION

Example embodiments of the present disclosure are directed to a cold plate structure including: a channel structure integrally formed with the cold plate structure and including a coolant; and a plurality of oscillating heat pipes integrally formed with the cold plate structure and configured to transfer heat from a target structure to the channel structure, wherein the plurality of oscillating heat pipes are fluidically isolated from the channel structure.

In any one or combination of the embodiments disclosed herein: a condenser region of the plurality of oscillating heat pipes is included in a first portion of the cold plate structure where the plurality of oscillating heat pipes and the channel structure overlap; an evaporator region of the plurality of oscillating heat pipes is included in a second portion of the cold plate structure where the plurality of oscillating heat pipes and the target structure overlap; and a height of the first portion of the cold plate structure is greater than a height of the second portion of the cold plate structure.

In any one or combination of the embodiments disclosed herein, for one or more oscillating heat pipes of the plurality of oscillating heat pipes: a first portion of the one or more oscillating heat pipes is manufactured using a first manufacturing process including powder bed fusion; and a second portion of the one or more oscillating heat pipes is manufactured using a second manufacturing process different from the first manufacturing process.

In any one or combination of the embodiments disclosed herein: the first portion includes a corner section or a curved section of the one or more oscillating heat pipes; and the second portion includes a linear section of the one or more oscillating heat pipes.

In any one or combination of the embodiments disclosed herein, the cold plate structure further includes: a second channel structure integrally formed with the cold plate structure and including the coolant, wherein the plurality of oscillating heat pipes are configured to transfer the heat from the target structure to the second channel structure, and the plurality of oscillating heat pipes are fluidically isolated from the second channel structure.

In some aspects, the techniques described herein relate to an assembly including: a printed wiring board; a target structure mounted to the printed wiring board; and a cold plate structure including: a channel structure integrally formed with the cold plate structure and including a coolant; and a plurality of oscillating heat pipes integrally formed with the cold plate structure and configured to transfer heat from the target structure to the channel structure, wherein the plurality of oscillating heat pipes are fluidically isolated from the channel structure.

Example embodiments of the present disclosure are directed to an assembly, wherein: a condenser region of the plurality of oscillating heat pipes is included in a first portion of the cold plate structure where the plurality of oscillating heat pipes and the channel structure overlap; an evaporator region of the plurality of oscillating heat pipes is included in a second portion of the cold plate structure where the plurality of oscillating heat pipes and the target structure overlap; and a height of the first portion of the cold plate structure is greater than a height of the second portion of the cold plate structure.

In any one or combination of the embodiments disclosed herein, for one or more oscillating heat pipes of the plurality of oscillating heat pipes: a first portion of the one or more oscillating heat pipes is manufactured using a first manufacturing process including laser powder bed fusion; and a second portion of the one or more oscillating heat pipes is manufactured using a second manufacturing process different from the first manufacturing process.

In any one or combination of the embodiments disclosed herein,: the first portion includes a corner section or a curved section of the one or more oscillating heat pipes; and the second portion includes a linear section of the one or more oscillating heat pipes.

In any one or combination of the embodiments disclosed herein, the cold plate structure further includes: a second channel structure integrally formed with the cold plate structure and including the coolant, wherein the plurality of oscillating heat pipes are configured to transfer the heat from the target structure to the second channel structure, and the plurality of oscillating heat pipes are fluidically isolated from the second channel structure.

Example embodiments of the present disclosure are directed to a method of manufacturing a cold plate structure, including: integrally forming a channel structure with a body of the cold plate structure using additive manufacturing; and integrally forming a plurality of oscillating heat pipes with the body of the cold plate structure, wherein the plurality of oscillating heat pipes are configured to transfer heat from a target structure to the channel structure and are fluidically isolated from the channel structure, wherein integrally forming the plurality of oscillating heat pipes includes, for one or more oscillating heat pipes of the plurality of oscillating heat pipes: forming a first portion of the one or more oscillating heat pipes using a first manufacturing process including laser powder bed fusion; and forming a second portion of the one or more oscillating heat pipes using a second manufacturing process different from the first manufacturing process.

In any one or combination of the embodiments disclosed herein: the first portion includes a corner section or a curved section of the one or more oscillating heat pipes; and the second portion includes a linear section of the one or more oscillating heat pipes.

In any one or combination of the embodiments disclosed herein, forming the second portion of the one or more oscillating heat pipes using the second manufacturing process includes: machining in a channel feature of the one or more oscillating heat pipes; and forming a capping layer over the channel feature .

In any one or combination of the embodiments disclosed herein, forming the capping layer over the channel feature includes using additive manufacturing.

In any one or combination of the embodiments disclosed herein, forming the first portion of the one or more oscillating heat pipes using the first manufacturing process is performed before forming the second portion of the one or more oscillating heat pipes using the second manufacturing process.

Additional features and advantages are realized through the techniques of the present disclosure. Other embodiments and aspects of the disclosure are described in detail herein and are considered a part of the claimed technical concept. For a better understanding of the disclosure with the advantages and the features, refer to the description and to the drawings.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 illustrates aspects of an assembly and a manifold structure that in accordance with one or more embodiments of the present disclosure.

FIG. 2A illustrates a plan view of a region of the assembly. FIG. 2B illustrates a side view of the region of the assembly.

FIGS. 3A and 3B illustrate aspects of a simplified thermal resistance network achieved by implementing a cold plate structure, oscillating heat pipes, and coolant channel structures in accordance with one or more embodiments of the present disclosure.

FIGS. 4A, 4B, and 4C illustrate aspects of an assembly manufactured using vacuum-brazing as a comparative example.

FIG. 5 illustrates an example flowchart of a manufacturing process supportive of manufacturing an assembly in accordance with one or more embodiments of the present disclosure.

FIGS. 6A-6D are views illustrating aspects of implementing the manufacturing process of FIG. 5.

FIG. 7 illustrates an example flowchart of a method of manufacturing a cold plate structure for a device assembly in accordance with one or more embodiments of the present disclosure.

### DETAILED DESCRIPTION

A detailed description of one or more embodiments of the disclosed apparatus and method are presented herein by way of exemplification and not limitation with reference to the Figures.

Energy density may often drive packaging to the limits of producibility. For example, for some standard vacuum brazed cold plates, manufacturing (i.e., producibility) constraints may drive a planar channel geometry that creates wasted space in an assembly. Accordingly, for example, with respect to airborne electronics packaging, it is becoming challenging to fit hardware within customer defined volumes. Standard mechanical design approaches may be unable to produce designs within customer requested volumes, namely driven by geometric deficiencies in thermal architectures and ties back to manufacturing constraints.

While additive manufacturing (AM) techniques can produce non-planar conformal cooling channels, the process may struggle to produce high-density features that perform to the same heat transfer coefficient / pressure drop as finstock material used in vacuum brazed cold plates. Coupled with the thermal conductivity of the cold plate material, such production issues may limit the energy density that AM cold plates can effectively handle with minimal/comparable temperature rise.

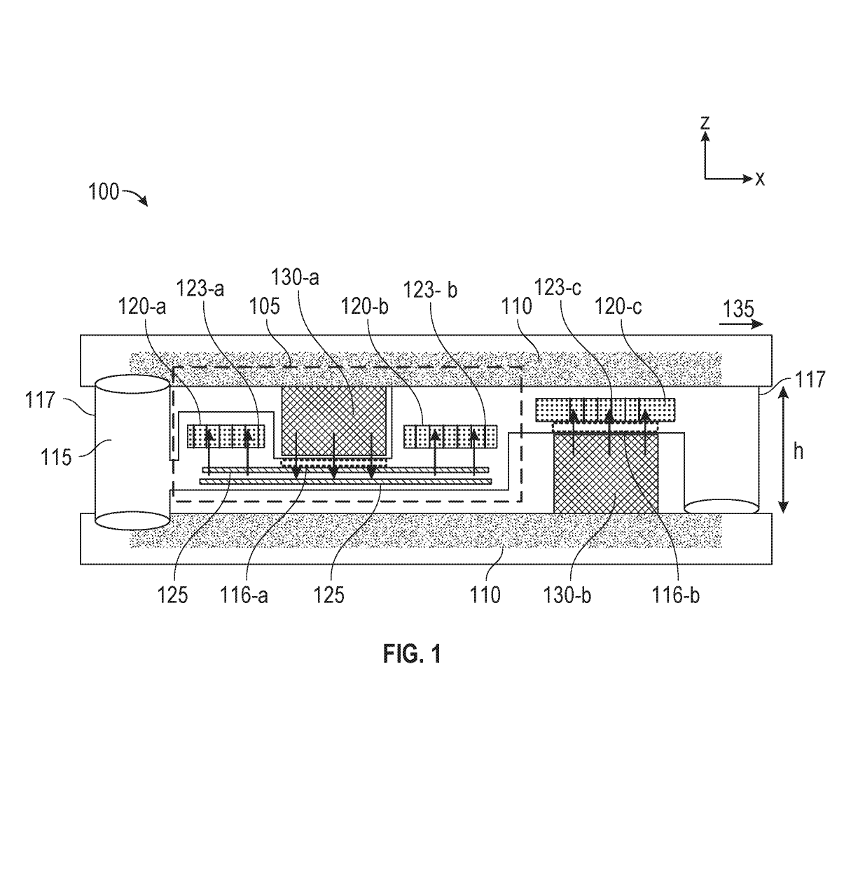

FIG. 1 illustrates aspects of an assembly 100 in accordance with one or more embodiments of the present disclosure.

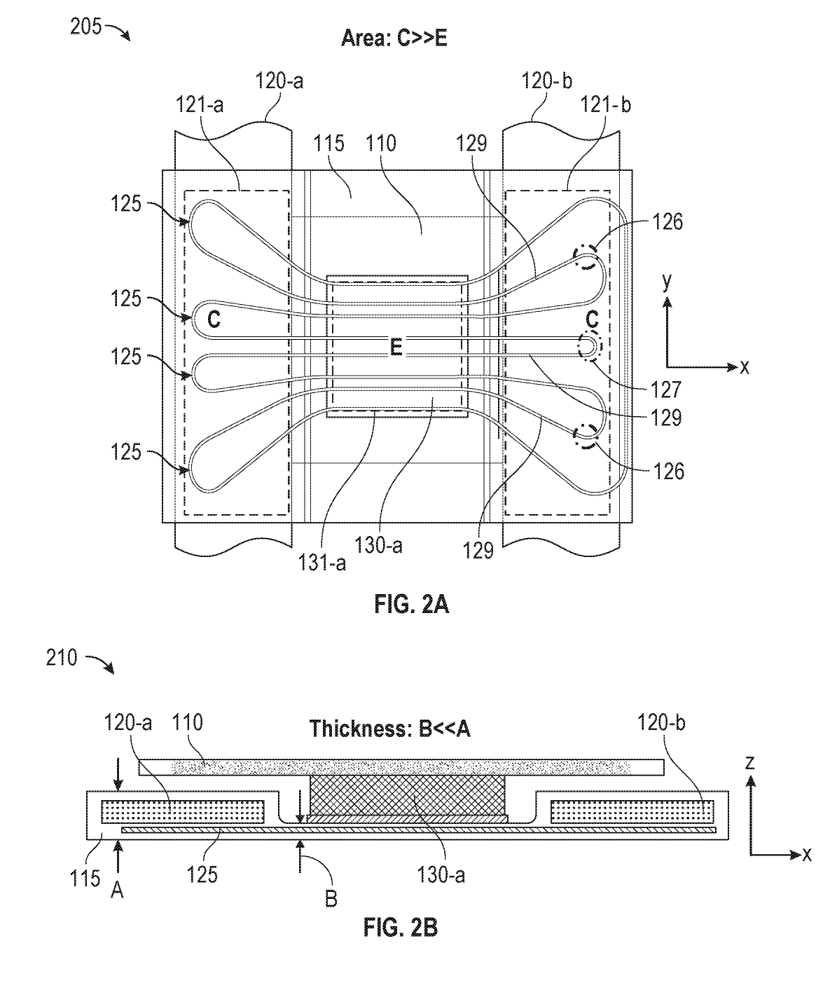

FIG. 2A illustrates a plan view 205 of a region 105 of the assembly 100. FIG. 2B illustrates a side view 210 of the region 105 of the assembly 100.

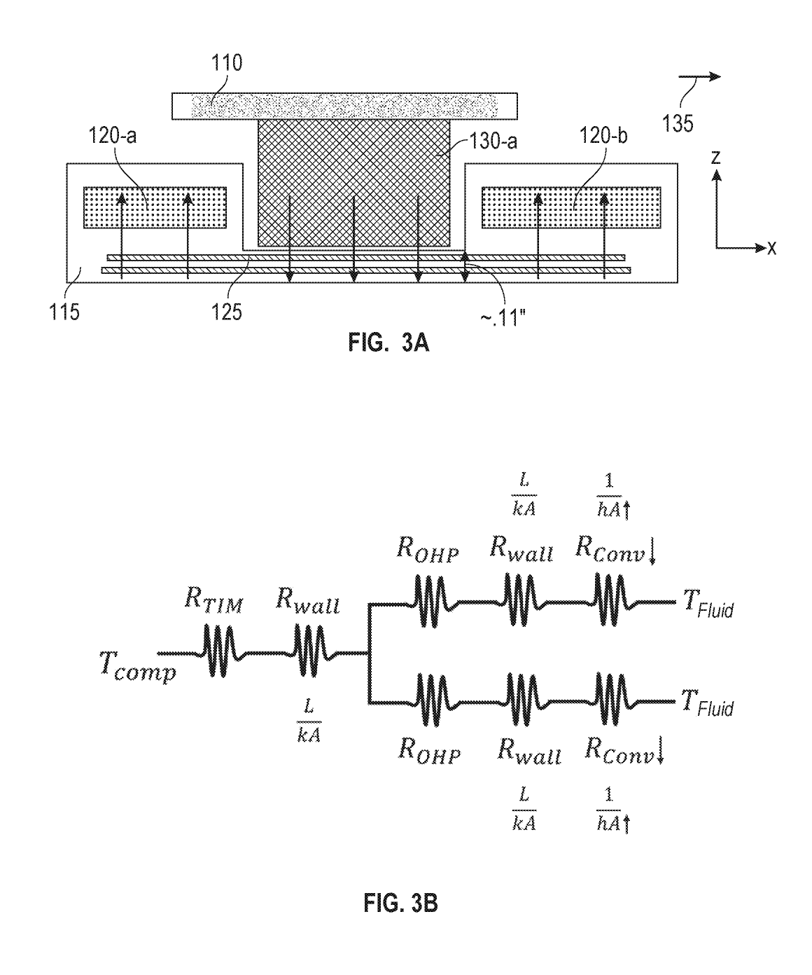

FIGS. 3A and 3B illustrate aspects of a simplified thermal resistance network achieved by implementing the cold plate structure 115, the oscillating heat pipes 125, and the coolant channel structures 120 in accordance with one or more embodiments of the present disclosure.

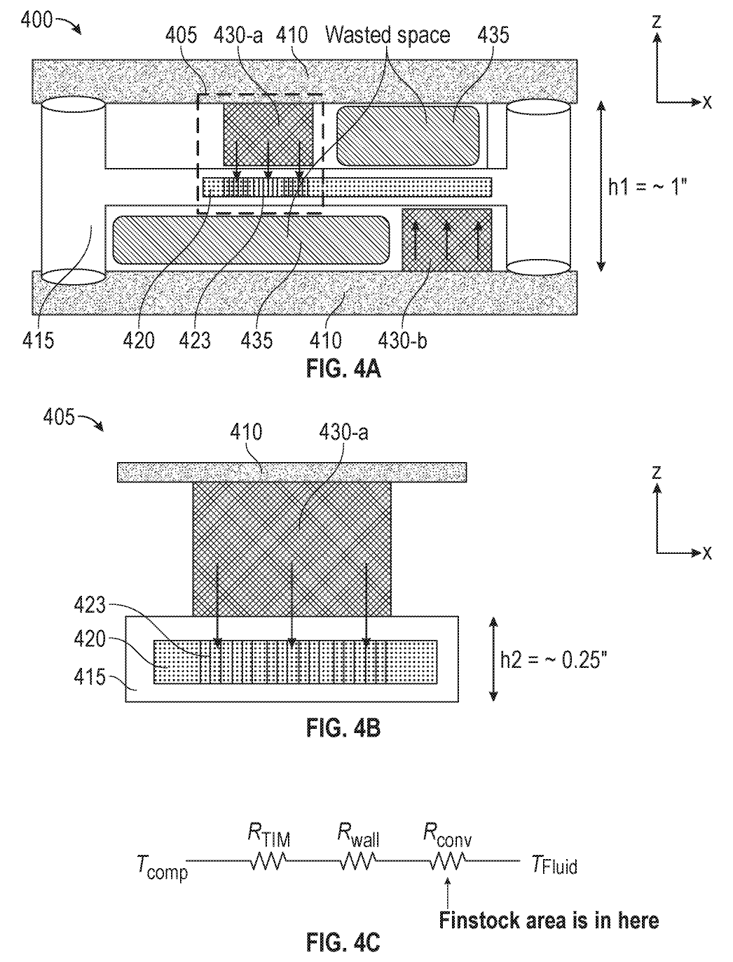

FIGS. 4A and 4B illustrate aspects of an assembly 400 manufactured using vacuum-brazing as a comparative example. FIG. 4C illustrates a thermal resistance network for the comparative example. The resistance from convection (R_{conv}) of FIG. 4C achieved through vacuum-brazing cannot be achieved with additive manufacturing. That is, the resistance from convection (R_{conv}) of FIG. 4C, as achieved through vacuum-brazing, is different from the resistance from convection (R_{conv}) of FIG. 3B achieved through additive manufacturing.

Example aspects of the assembly 100 will be described herein with reference to FIGS. 1, 2A, 2B, 3A, and 3B. Aspects of the assembly 100 will be further described herein with reference to the comparative example of FIGS. 4A, 4B, and 4C.

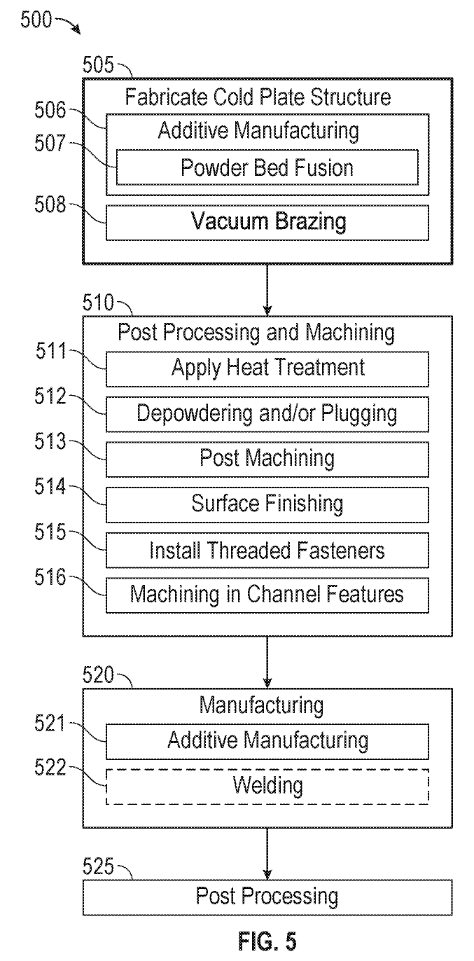

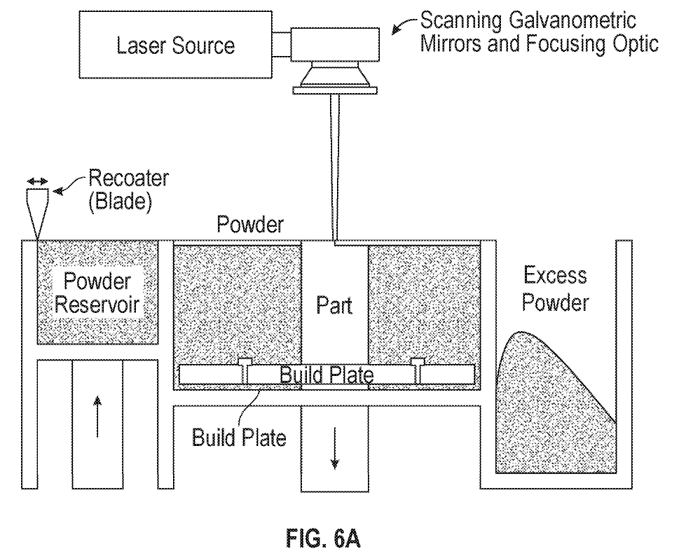

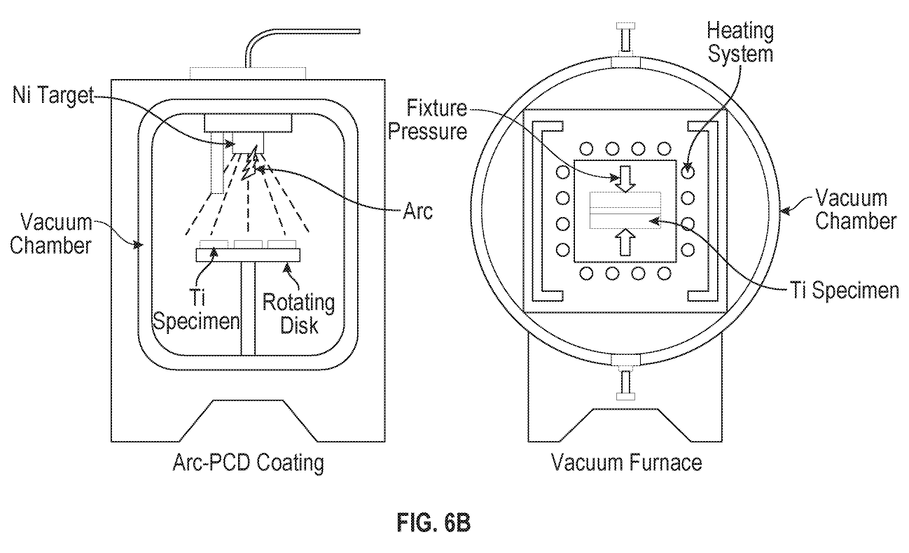

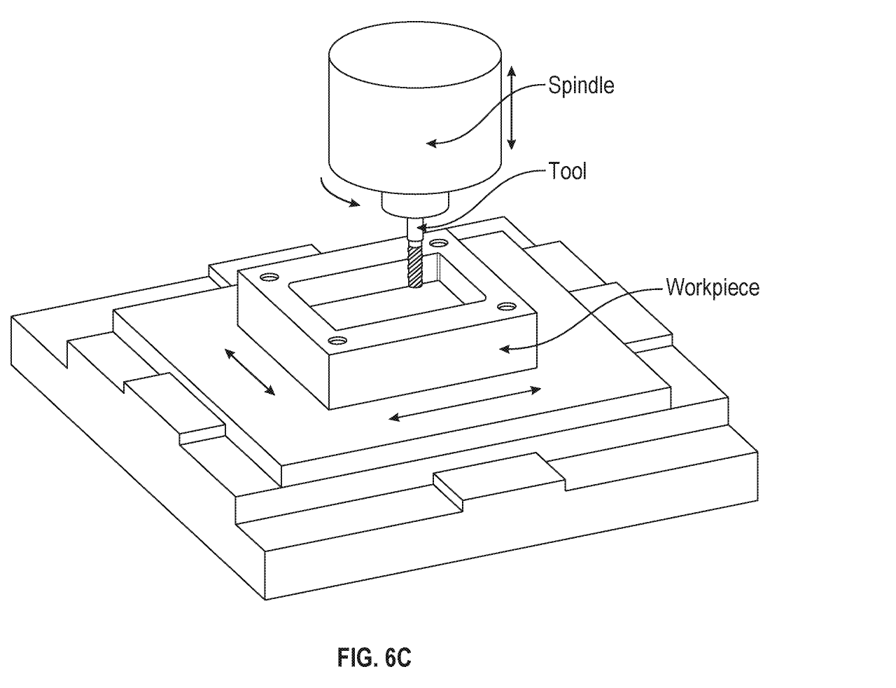

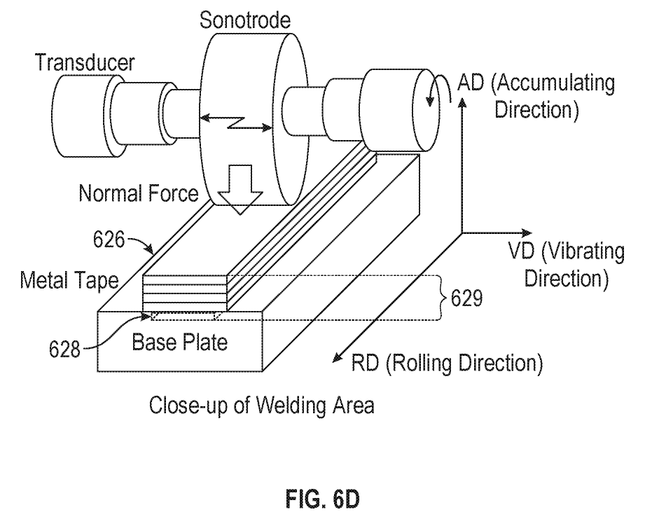

With reference to FIG. 1, the assembly 100 may include printed wiring boards 110, a cold plate structure 115 (also referred to herein as a cold plate part), coolant channel structures 120, fin structures 123 (each including a set of fins), and oscillating heat pipes 125. The cold plate structure 115, the coolant channel structures 120, the fin structures 123, and the oscillating heat pipes 125 may be manufactured using a manufacturing process in accordance with one or more embodiments of the present disclosure (a manufacturing process 500 later described herein with reference to FIGS. 5 and 6A-6D).

The cold plate structure 115 may include heatsink portions 116 (e.g., heatsink portion 116-a, heatsink portion 116-b), support portions 117, and other structural portions. In some embodiments, the coolant channel structures 120, he fin structures 123, and the oscillating heat pipes 125 may be integrally formed with the cold plate structure 115. In accordance with one or more embodiments of the present disclosure, each of the coolant channel structures 120, the fin structures 123, and the oscillating heat pipes 125 are embedded in at least a portion of the cold plate structure 115.

The assembly 100 may include target structures 130 to be cooled using the cold plate structure 115 (e.g., using the coolant channel structures 120, the fin structures 123, and the oscillating heat pipes 125). Non-limiting examples of the target structures 130 include an electrical component, an application specific integrated circuit (ASIC), a field programmable gate array (FPGA), or any target structure to be cooled. Each target structure 130 may be mounted to a respective printed wiring board 110 and be thermal coupled to a portion (e.g., a heatsink portion 116) of the cold plate structure 115.

With reference to region 105, the cold plate structure 115 is embedded with two-phase heat spreading which supports effective dispersal of heat associated with target structure 130-a via the oscillating heat pipes 125 and the fin structures 123. The arrows 135 represent heat dissipation. The fin structures 123 may be a part of the coolant channel structures 120, and the coolant channel structures 120 may shuttle a pumped coolant liquid (not illustrated). In some examples, the coolant liquid may be a forced convection liquid coolant.

Aspects of the present disclosure provide a combined use of cooling elements (e.g., cold plate structure 115, coolant channel structures 120, fin structures 123, oscillating heat pipes 125) integrated in the same body through a manufacturing process (e.g., manufacturing process 500 later described herein) which overcomes manufacturing complexities associated with incorporating oscillating heat pipe technology and constraints associated with additive manufacturing of fin structures.

The oscillating heat pipes 125 support transporting and distributing heat energy from a source to a larger area that is directly adjacent to a bulk channel with flowing liquid coolant. For example, with reference to FIGS. 1 and 2A, the oscillating heat pipes 125 may transport and distribute heat energy from an area 131-a associated with the target structure 130-a to area 121-a and area 121-b. The area 131-a may also be referred to as area ‘E’ (i.e., for heat energy), and the area 121-a and the area 121-b may also be referred to as areas ‘C’ (i.e., for cooling).

The area 131-a may be based on an overlap between the oscillating heat pipes 125 and the target structure 130-a. For example, the area 131-a may correspond to the area of the heatsink portion 116-a. For example, the area 131-a may correspond to the heatsink portion 116-a where the target structure 130-a contacts the cold plate structure 115.

The area 121-a and the area 121-b may be based on respective overlaps between the oscillating heat pipes 125 and the coolant channel structure 120-a and the coolant channel structure 120-b. In some embodiments, each of the area 121-a and the area 121-b may be greater than the area 131-a. For example, the size ‘C’ of each of the area 121-a and the area 121-b may be about two times greater (or more) than the size ‘E’ of the area 131-a, but embodiments of the present disclosure are not limited thereto. In the example of FIG. 2A, the size ‘C’ of each of the area 121-a and the area 121-b is about five times greater than the size ‘E’ of the area 131-a, but embodiments of the present disclosure are not limited thereto. Embodiments of the present disclosure support variations of the size ‘C’ of each of the area 121-a and the area 121-b m and the size ‘E’ of the area 131-a based on target performance parameters for cooling electronic components (i.e., target cooling for the target structure 130-a), target design specifications (i.e., available area within the assembly 100, size specifications of the electronic components, or the like), and other design criteria.

Example aspects of features provided by the oscillating heat pipes 125 are described herein. In the area 131-a, heat (e.g., from the target structure 130-a) may be absorbed by liquid segments, and tails of the liquid segments may change into a vapor (vapor state). Vapor segments adjacent to the liquid may expand. Portions of the liquid which carry heat may be pushed by the vapor segments to the area 121-a and the area 121-b.

In the area 121-a and the area 121-b, heat is removed from liquid segments due to thermal coupling between the oscillating heat pipes 125 and overlapping portions of the coolant channel structure 120-a and the coolant channel structure 120-b. In the area 121-a and the area 121-b, vapor condenses back into a liquid, and adjacent liquid segments rejoin. Accordingly, for example, at the area 121-a and the area 121-b, vapor segments may shrink based on the removal of heat from the liquid segments and the vapor.

The vapor, as described herein, moves liquid to and from the area 121-a (and similarly the area 121-b) and the area 131-a. The example events described with reference to the oscillating heat pipes 125 may occur simultaneously across one or more serpentine passes (e.g., several serpentine passes) included among the oscillating heat pipes 125 and induce a chaotic oscillatory motion. With respect to the functionality of the oscillating heat pipes 125, the area 121-a and the area 121-b may be referred to as cooling regions or condenser regions, and the area 131-a may be referred to as an evaporator region.

The oscillating heat pipes 125 may reside in isolated cavities with respect to one another. The coolant channel structures 120 may reside in isolated cavities with respect to one another. Further, the oscillating heat pipes 125 may reside in isolated cavities with respect to the coolant channel structures 120. Accordingly, for example, the assembly 100 described herein provides a dual phase working fluid (implemented in the oscillating heat pipes 125) and pumped liquid coolant (implemented in the coolant channel structures 120) performing work within the same body (i.e., the cold plate structure 115), in which the dual phase working fluid and the pumped liquid coolant reside in isolated cavities from each other. Aspects of the manufacturing process 500 later described herein support the manufacturing of the assembly 100.

The cold plate structure 115, the coolant channel structures 120, the fin structures 123, and the oscillating heat pipes 125, and the manufacturing process 500 support reducing the thickness of packaged electronics while maintaining a target amount of cooling, without the use of high density finstock. For example, with reference to FIG. 1, manufacturing techniques described herein support the formation of conformal channels (i.e., coolant channel structures 120) which occupy space around target structures 130, allowing for ‘meshing’ of opposing boards (i.e., printed wiring boards 110).

In the assembly 100, heat generated by target structures 130 having high energy density may be distributed via oscillating heat pipes 125, which may reduce the reliance on high-density finstock. Accordingly, for example, aspects of the assembly 100 overcome problems of reduced fin density associated with fin structures 123 manufactured through additive manufacturing compared to fin structures manufactured using vacuum brazing (e.g., fin structure 423 later described herein with reference to FIGS. 4A, 4B, and 4C).

For example, as illustrated by the example of FIG. 1, the assembly 100 manufactured in accordance with the manufacturing techniques described herein is able to incorporate fin structures 123 in multiple locations, thereby distributing heat from the target structure 130-a to the multiple locations. Accordingly, for example, though the fin density associated with the fin structures 123 manufactured through additive manufacturing may be relatively less compared to fin structures manufactured using vacuum brazing, the assembly 100 may be designed and manufactured such that the overall fin area provided by fin structure 123-a and fin structure 123-b is equal to or greater than an overall fin area provided by the fin structure 423 (illustrated at FIGS. 4A and 4B) manufactured through vacuum brazing.

Accordingly, the heat transfer provided by the fin structure 123-a and the fin structure 123-b may be equal to or greater than the heat transfer provided by the fin structure 423, while reducing the amount of wasted space and the height h of the assembly 100 compared to other approaches. For example, in accordance with one or more embodiments of the present disclosure, the height h of the assembly 100 may range from about 0.5 inches to about 0.75 inches in the Z direction, whereas the comparative implementation of an assembly 400 including a cold plate 415 (manufactured using vacuum brazing) may have a height h1 of greater than 1 inch in the Z direction.

With reference to FIG. 2B, a thickness B associated with an inner portion of the cold plate structure 115 in contact with the target structure 130-a may be less than a thickness A associated with outer portions of the cold plate structure 115. For example, the thickness B for the inner portion may be about 0.25”, and the thickness A for the outer portion may be about 1.0”, but embodiments of the present disclosure are not limited thereto.

FIGS. 3A and 3B illustrate aspects of thermal conductivity achieved by implementing the cold plate structure 115, the coolant channel structures 120, the fin structures 123, and the oscillating heat pipes 125, in accordance with one or more embodiments of the present disclosure. The arrows 135 represent heat dissipation.

In accordance with one or more embodiments of the present disclosure, the oscillating heat pipes 125, which are embedded in the cold plate structure 115, distribute heat energy from the target structure 130-a over channel sections (i.e., coolant channel structure 120-a and coolant channel structure 120-b) having an overall larger area compared to channel sections (i.e., coolant channel structure 420 of FIG. 4A) of other approaches. Aspects of the cold plate structure 115, the coolant channel structures 120, and the oscillating heat pipes 125 described herein enhance a heat transfer through spreading the heat energy over a large area through the coolant channel structure 120-a and the coolant channel structure 120-b, which have a high effective thermal conductivity. In some aspects, the effective thermal conductivity of the coolant channel structure 120-a and the coolant channel structure 120-b may be 2 orders of magnitude greater than the thermal conductivity of metal.

As has been described herein with reference to FIGS. 1, 2A, 2B, 3A, and 3B, an assembly 100 (a device) is provided having a design that includes bulk flow paths for pumped liquid coolant that are routed to be conformal, such that the bulk flow paths occupy space directly adjacent to a target geometry (e.g., a target structure 130).

Oscillating heat pipes 125 embedded in the assembly 100 remain fluidically isolated from coolant channel structures 120 (also referred to herein as bulk cooling channels or bulk flow channels), but are placed in a way which supports efficiently dispersing and transferring energy from a target structure 130 (a highly concentrated (energy dense) source) to the coolant channel structures 120. The assembly 100 utilizes the combination of both the coolant channel structures 120 and the oscillating heat pipes 125 to disperse thermal energy over a large area with a minimal temperature rise to the target structure 130, which is a heat producing part. Accordingly, for example, the structure formed by the integral formation of the oscillating heat pipes 125 and the coolant channel structures 120 into the cold plate structure 115 may be referred to herein as a small layered inter-phase manifold (SLIM).

In some aspects, the dispersal of the thermal energy with minimal temperature rise to the target structure 130 is achieved due to the very low thermal resistance of oscillating heat pipes 125 compared to the thermal resistance of conduction through solid metal.

Aspects of the assembly 100 achieve a lower coolant flow resistance, as illustrated at FIG. 3B. With reference to FIG. 3B, T_{comp} refers to temperature of the target structure 130-a, R_{TIM} refers to resistance of a thermal interface material (not illustrated) between the target structure 130-a and the cold plate structure 115, R_{wall} refers to resistance of the portion of the cold plate structure 115 between the target structure 130-a and the oscillating heat pipes 125, R_{OHP} refers to resistance of the oscillating heat pipes 125, R_{wall} refers to resistance of portions of the cold plate structure 115 between the oscillating heat pipes 125 and the coolant channel structures 120, R_{conv} is the convective resistance (thermal resistance) of the surfaces against heat convection (i.e., the resistance to the cold sink fluid), and T_{fluid} refers to the temperature of the coolant in the coolant channel structures 120.

R_{OHP} is low, allowing heat to spread away from the heat source (i.e., target structure 130-a) towards a larger heat sink area, which creates for a lower convective resistance R_{conv} to the heat sink fluid, T_{F}.

FIG. 3B demonstrates that heat is spread over a larger area (denoted by two parallel paths along with the “up” arrows by the “A” in the formula “1/hA”). This larger A leads to a lower convective resistance R_{conv}. This lower convective resistance R_{conv} leads to an increased heat transfer.

The assembly 100 achieves a high thermal conductivity value (K-value) and supports spread heat associated with the target structure 130-a over a relatively large area (e.g., combined area of area 121-a and area 121-b).

With reference to FIGS. 4A and 4B, a discussion of the assembly 400 of the comparative example, problems associated with the assembly 400, region 405 of the assembly 400, and how aspects of the assembly 100 in accordance with one or more embodiments of the present disclosure overcome or address the problems is provided.

The assembly 400 may include printed wiring boards 410, a cold plate structure 415, a coolant channel structure 420, a fin structure 423, and target structures 430 (e.g., target structure 430-a, target structure 430-b) to be cooled. Repeated descriptions of like elements are omitted for brevity.

The cold plate structure 415 is a vacuum-brazed cold plate. Due to vacuum brazing, the cold plate structure 415 is constrained to planar geometry, and the stack-up height h1 of the assembly 400 is sensitive to the heights of the tallest components incorporated into the assembly 400. Manufacturing and/or producibility constraints associated with vacuum brazing result in a drive planar channel geometry that creates wasted space 435 in the assembly 400.

In an example, the stack-up height h1 of the assembly 400 may be greater than or equal to 1 inch in the Z direction. A height h2 of the portion of the cold plate structure 415 which contacts the target structures 430 (and includes the coolant channel structure 420 and the fin structure 423) may be about 0.25 inches. In the comparative example, the height h2 is more than double the thickness B of the inner portion of the cold plate structure 115 of FIG. 1 which is in contact with the target structure 130-a.

The fin structure 423 (provided through vacuum brazing) of the assembly 400 may have a higher density of fins compared to the fin structures 123 (manufactured using additive manufacturing) of the assembly 100 due to the finstock implemented in the fin structure 423 of the assembly 400. The cold plate structure 415 enhances a heat transfer with close large area through a thin proximity of aluminum material. For example, the cold plate structure 415 enhances the heat transfer of finstock due to the close proximity of large wetted area of the finstock to the heat source. Additionally, the low thermal resistance of the thin aluminum skin between the heat source and the finstock is beneficial. However, the finstock density in the approach described with reference to FIGS. 4A-4C is highly difficult to achieve (i.e., unachievable) with additive manufacturing methods. Accordingly, the techniques described herein overcome such shortcomings associated with some other manufacturing approaches.

In contrast, the assembly 100 provided in accordance with one or more embodiments of the present disclosure has a reduced stack-up height h (stack-up thickness) compared to the height h1 of the assembly 400 manufactured using vacuum brazing. Further, though fin structures 123 (manufactured using additive manufacturing) of the assembly 100 may have fins which are relatively less dense compared to finstock implemented in the fin structure 423 of the assembly 400, the assembly 100 mitigates such characteristics of the fin structures 123 through the configuration and functions of the cold plate structure 115, the coolant channel structures 120, the fin structures 123, and the oscillating heat pipes 125 described herein, through spreading the heat energy of a target structure 130 over a relatively larger area compared to the assembly 400.

FIG. 5 illustrates an example flowchart of a manufacturing process 500 (method) supportive of manufacturing an assembly 100 of FIG. 1, and particularly, the cold plate structure 115, the coolant channel structures 120, the fin structures 123, and the oscillating heat pipes 125 in accordance with one or more embodiments of the present disclosure. FIGS. 6A-6D are views illustrating aspects of equipment associated with implementing the manufacturing process 500.

At block 505, the manufacturing process 500 includes fabricating the cold plate structure 115 with the coolant channel structures 120, in which the coolant channel structures 120 are conformal primary coolant channels (channel features). Aspects of equipment associated with implementing block 505 of the manufacturing process 500 are illustrated at FIGS. 6A and 6B.

With respect to block 505, aspects of the manufacturing process 500 may include metal additive manufacturing (AM) at block 506. In an example, the additive manufacturing may include powder bed fusion (PBF). For example, the additive manufacturing may include laser powder bed fusion (L-PBF), which includes depositing, melting, and solidifying a layer of metal powder using a laser to create a solid layer of metal, and further, joining consecutive 2D layers to preceding layers to build up fully solid 3D components. Additionally, or alternatively, the additive manufacturing may include electron beam powder bed fusion (EPBF).

Aspects of block 505 of the manufacturing process 500 may further include vacuum brazing at block 508, which includes joining together components (i.e., the components formed through additive manufacturing (i.e., PBF) described with reference to block 506 and block 507) using a filler metal referred to as a brazing alloy.

At block 510, the manufacturing process 500 includes post processing and machining. Aspects of equipment associated with implementing block 510 of the manufacturing process 500 are illustrated at FIG. 6C.

For example, with respect to block 510, the manufacturing process 500 includes applying a heat treatment at block 511, performing depowdering and/or plugging at block 512, performing post machining of mounting features at block 513, performing surface finishing at 514, installing threaded fasteners at block 515, and machining in channel features of the oscillating heat pipes 125 at block 516.

At block 520, the manufacturing process 500 includes a manufacturing process of further performing additive manufacturing (at block 521). Aspects of implementing manufacturing at block 520 of the manufacturing process 500 are illustrated at FIG. 6D.

Performing additive manufacturing at block 521 may include forming capping layers 626 through diffusion bonding, ultrasonic additive manufacturing, or electrochemical additive manufacturing. The capping layers 626 may together be formed as a laminate. In some aspects, performing the additive manufacturing at block 521 may further secure the capping layers 626 over top of oscillating heat pipe channels 628 (e.g., through diffusion bonding, ultrasonic additive manufacturing, or electrochemical additive manufacturing), effectively completing longitudinal sections 629 of oscillating heat pipes.

Embodiments of the present disclosure may include implementing the manufacturing process 500 with or without performing welding at block 522. For example, in some cases, performing welding at block 522 may include welding the capping layers 626 over top of oscillating heat pipe channels 628, effectively completing longitudinal sections 629 of oscillating heat pipes. The welding process may include applying pressure to the capping layers 626 in a normal force direction.

In some aspects, the oscillating heat pipe channels 628 may be flat, planar, openings, but embodiments of the present disclosure are not limited thereto. For example, bottom surfaces or side surfaces of the oscillating heat pipe channels 628 may be flat, inclined with respect to the accumulating direction, or concave in a direction opposite to the accumulating direction.

At block 525, the manufacturing process 500 includes performing post processing of machine integration features. Aspects of implementing block 525 of the manufacturing process 500 are illustrated at FIG. 6C.

In some aspects, performing post processing at block 525 may include coating, surface finishing (e.g., of features formed through ultrasonic additive manufacturing) as applicable, and charging the oscillating heat pipes. Charging the oscillating heat pipes may include providing a suitable amount of liquid into the oscillating heat pipes that supports operation of the oscillating heat pipes in accordance with target specifications.

An example implementation of the manufacturing process 500 in association with manufacturing channel features of oscillating heat pipes 125 is further described with reference back to FIG. 2A.

The manufacturing process 500 may include using powder bed fusion (PBF) at block 507 for forming portions of the oscillating heat pipes 125 which have a relatively higher complexity. The powder bed fusion may be, for example, laser powder bed fusion (L-PBF) or electron beam powder bed fusion (EPBF). For example, in some cases, corner sections 126 and other curved sections 127 of the oscillating heat pipes 125 may be relatively difficult to manufacture compared to relatively straight sections 129 (linear sections) of the oscillating heat pipes 125. Accordingly, for example, at block 507, the manufacturing process 500 may use PBF to pre-form such corner sections 126 and other curved sections 127 as hollow cavities or hollow channels. At block 510, the manufacturing process 500 may form the relatively straight sections 129.

That is, at block 506, the manufacturing process 500 may manufacture additive preforms which contain sections (e.g., corner sections 126, other curved sections 127) of the oscillating heat pipe channel network, and the manufacturing process 500 may depowder the preforms or sections at block 512. The manufacturing process 500 may then machine the remainder (e.g., relatively straight sections 129) of the oscillating heat pipe channel network at block 516. These embedded OHP channel sections may be non-planar, or routed in 3-dimensions.

Accordingly, for example, the manufacturing process 500 may provide oscillating heat pipes 125 in which relatively straight sections 129 are pre-fitted to corner sections 126 and curved sections 127, thereby providing an effective hermetic seal and fluid communication among the relatively straight sections 129 and the corner sections 126 and curved sections 127. Aspects of the manufacturing process 500 may prevent the corner sections 126 other curved sections 127 from becoming weak points of the oscillating heat pipes 125.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

Aspects of the cold plate structure 115, the coolant channel structures 120, the fin structures 123, the oscillating heat pipes 125, and the associated manufacturing techniques described herein provide an enhanced cooling architecture supportive of electronics miniaturization and application towards products that involve high heat extraction and function with small and dense packages. For example, aspects of the cold plate structure 115, the coolant channel structures 120, the fin structures 123, the oscillating heat pipes 125, and the associated manufacturing techniques described herein provide thermal solutions having oscillating heat pipe applications and two phased cooling applications which may be advantageously applied to dense electronics packaging (e.g., RF packaging, digital processor packaging, electro-optical packaging, control systems, battery packs, and the like).

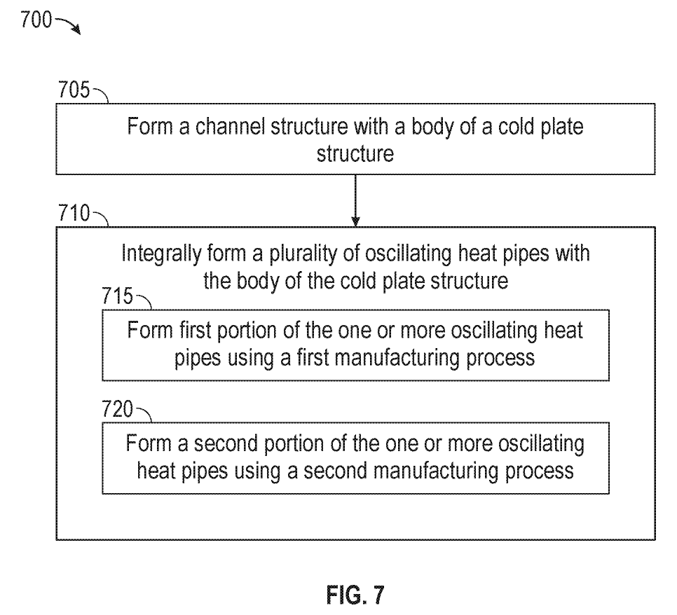

FIG. 7 illustrates an example flowchart of a method 700 of manufacturing a cold plate structure for a device assembly in accordance with one or more embodiments of the present disclosure.

At 705, the method 700 includes integrally forming a channel structure with a body of the cold plate structure using additive manufacturing.

At 710, the method 700 includes integrally forming a plurality of oscillating heat pipes with the body of the cold plate structure, wherein the plurality of oscillating heat pipes are configured to transfer heat from a target structure to the channel structure and are fluidically isolated from the channel structure.

In some aspects, integrally forming the plurality of oscillating heat pipes includes, for one or more oscillating heat pipes of the plurality of oscillating heat pipes: forming (at 715) a first portion of the one or more oscillating heat pipes using a first manufacturing process including powder bed fusion; and forming (at 720) a second portion of the one or more oscillating heat pipes using a second manufacturing process different from the first manufacturing process.

In some aspects, the first portion includes a corner section or a curved section of the one or more oscillating heat pipes; and the second portion includes a linear section of the one or more oscillating heat pipes.

In some aspects, forming the second portion of the one or more oscillating heat pipes using the second manufacturing process includes: machining in a channel feature of the one or more oscillating heat pipes; and forming a capping layer over the channel feature.

In some aspects, forming the capping layer over the channel feature includes using ultrasonic additive manufacturing.

In some aspects, forming the first portion of the one or more oscillating heat pipes using the first manufacturing process is performed before forming the second portion of the one or more oscillating heat pipes using the second manufacturing process.

In the descriptions of the flowcharts herein, the operations may be performed in a different order than the order shown, or the operations may be performed in different orders or at different times. Certain operations may also be left out of the flowcharts, one or more operations may be repeated, or other operations may be added to the flowcharts.

The term “about” is intended to include the degree of error associated with measurement of the particular quantity based upon the equipment available at the time of filing the application.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

The corresponding structures, materials, acts and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the technical concepts in the form disclosed. Many modifications and variations will be apparent to those of ordinary skill in the art without departing from the scope and spirit of the disclosure. The embodiments were chosen and described in order to best explain the principles of the disclosure and the practical application and to enable others of ordinary skill in the art to understand the disclosure for various embodiments with various modifications as are suited to the particular use contemplated.

While the various embodiments to the disclosure have been described, it will be understood that those skilled in the art, both now and in the future, may make various improvements and enhancements which fall within the scope of the claims which follow. These claims should be construed to maintain the proper protection for the disclosure first described.

What is claimed is:

1. A cold plate structure comprising:
a channel structure integrally formed with the cold plate structure and comprising a coolant; and
a plurality of oscillating heat pipes integrally formed with the cold plate structure and configured to transfer heat from a target structure to the channel structure,
wherein the plurality of oscillating heat pipes are fluidically isolated from the channel structure.

2. The cold plate structure of claim 1, wherein:
a condenser region of the plurality of oscillating heat pipes is comprised in a first portion of the cold plate structure where the plurality of oscillating heat pipes and the channel structure overlap;
an evaporator region of the plurality of oscillating heat pipes is comprised in a second portion of the cold plate structure where the plurality of oscillating heat pipes and the target structure overlap; and
a height of the first portion of the cold plate structure is greater than a height of the second portion of the cold plate structure.

3. The cold plate structure of claim 1, wherein for one or more oscillating heat pipes of the plurality of oscillating heat pipes:
a first portion of the one or more oscillating heat pipes is manufactured using a first manufacturing process comprising powder bed fusion; and
a second portion of the one or more oscillating heat pipes is manufactured using a second manufacturing process different from the first manufacturing process.

4. The cold plate structure of claim 3, wherein:
the first portion comprises a corner section or a curved section of the one or more oscillating heat pipes; and
the second portion comprises a linear section of the one or more oscillating heat pipes.

5. The cold plate structure of claim 1, further comprising:
a second channel structure integrally formed with the cold plate structure and comprising the coolant,
wherein the plurality of oscillating heat pipes are configured to transfer the heat from the target structure to the second channel structure, and the plurality of oscillating heat pipes are fluidically isolated from the second channel structure.

6. An assembly comprising:
a printed wiring board;
a target structure mounted to the printed wiring board; and
a cold plate structure comprising:
a channel structure integrally formed with the cold plate structure and comprising a coolant; and
a plurality of oscillating heat pipes integrally formed with the cold plate structure and configured to transfer heat from the target structure to the channel structure, wherein the plurality of oscillating heat pipes are fluidically isolated from the channel structure.

7. The assembly of claim 6, wherein:
a condenser region of the plurality of oscillating heat pipes is comprised in a first portion of the cold plate structure where the plurality of oscillating heat pipes and the channel structure overlap;
an evaporator region of the plurality of oscillating heat pipes is comprised in a second portion of the cold plate structure where the plurality of oscillating heat pipes and the target structure overlap; and
a height of the first portion of the cold plate structure is greater than a height of the second portion of the cold plate structure.

8. The assembly of claim 6, wherein for one or more oscillating heat pipes of the plurality of oscillating heat pipes:
a first portion of the one or more oscillating heat pipes is manufactured using a first manufacturing process comprising laser powder bed fusion; and
a second portion of the one or more oscillating heat pipes is manufactured using a second manufacturing process different from the first manufacturing process.

9. The assembly of claim 8, wherein:
the first portion comprises a corner section or a curved section of the one or more oscillating heat pipes; and
the second portion comprises a linear section of the one or more oscillating heat pipes.

10. The assembly of claim 6, wherein the cold plate structure further comprises:
a second channel structure integrally formed with the cold plate structure and comprising the coolant,
wherein the plurality of oscillating heat pipes are configured to transfer the heat from the target structure to the second channel structure, and the plurality of oscillating heat pipes are fluidically isolated from the second channel structure.

11. A method of manufacturing a cold plate structure, comprising:
integrally forming a channel structure with a body of the cold plate structure using additive manufacturing; and
integrally forming a plurality of oscillating heat pipes with the body of the cold plate structure, wherein the plurality of oscillating heat pipes are configured to transfer heat from a target structure to the channel structure and are fluidically isolated from the channel structure,
wherein integrally forming the plurality of oscillating heat pipes comprises, for one or more oscillating heat pipes of the plurality of oscillating heat pipes:
forming a first portion of the one or more oscillating heat pipes using a first manufacturing process comprising powder bed fusion; and
forming a second portion of the one or more oscillating heat pipes using a second manufacturing process different from the first manufacturing process.

12. The method of claim 11, wherein:
the first portion comprises a corner section or a curved section of the one or more oscillating heat pipes; and
the second portion comprises a linear section of the one or more oscillating heat pipes.

13. The method of claim 11, wherein forming the second portion of the one or more oscillating heat pipes using the second manufacturing process comprises:
machining in a channel feature of the one or more oscillating heat pipes; and
forming a capping layer over the channel feature.

14. The method of claim 13, wherein forming the capping layer over the channel feature comprises using additive manufacturing.

15. The method of claim 11, wherein forming the first portion of the one or more oscillating heat pipes using the first manufacturing process is performed before forming the second portion of the one or more oscillating heat pipes using the second manufacturing process.
